(19) United States
(12) Patent Application Publication
(10) Pub. No.: US 2025/0169254 A1
(43) Pub. Date: May 22, 2025

(54) OPTOELECTRONIC LIGHTING DEVICE AND METHOD

(71) Applicant: ams-OSRAM International GmbH, Regensburg (DE)

(72) Inventors: Patrick HOERNER, Bamberg (DE); Erwin LANG, Regensburg (DE); Michael JOBST, Wiesenfelden (DE); Andreas RAUSCH, Tegernheim (DE)

(21) Appl. No.: 18/841,249

(22) PCT Filed: Feb. 23, 2023
(86) PCT No.: PCT/EP2023/054522

§ 371 Date: Aug. 23, 2024

(30) Foreign Application Priority Data
Feb. 24, 2022 (DE) 10 2022 104 459.9

(51) Int. Cl. H10H 20/857; H10H 20/01; H10H 20/84

(52) U.S. Cl. CPC H10H 20/857; H10H 20/0364; H10H 20/84

(57) ABSTRACT

An optoelectronic lighting device includes a first at least partially transparent embedding layer and at least one at least partially transparent carrier substrate arranged on the first embedding layer, on whose side facing the first embedding layer a structured electrically conductive layer and at least one optoelectronic semiconductor component are arranged. The first embedding layer embeds the structured electrically conductive layer and the optoelectronic semiconductor component. The optoelectronic semiconductor component is configured to emit light at least along a main emission direction through a top surface of the optoelectronic semiconductor component and in a direction opposite to the main emission direction through a bottom surface of the optoelectronic semiconductor component. A substantially opaque region is provided below the optoelectronic semiconductor component, as viewed in the direction opposite to the main emission direction.

The present application claims the priority of German patent application No. 10 2022 104 459.9 dated Feb. 24, 2022, the disclosure of which is hereby incorporated by reference into the present application.

The present invention relates to technologies for displaying information in or on a transparent pane or surface of a vehicle. In particular, the invention relates to a pane, a window, a panoramic roof glazing, a headliner or a further surface of a vehicle, comprising optoelectronic semiconductor components, as well as their wiring and control, in order to display information or symbols on the pane, the window, the panoramic roof glazing, the headliner or the further surface of the vehicle.

Although the invention mainly addresses windshields, windows, panoramic roof glazing, a headliner and exterior surfaces of a car, it is not limited to this particular type of vehicle, but can alternatively be implemented in other types of vehicles such as trains, buses, trucks, airplanes, or ships.

Furthermore, the object of the present invention can also be used in the field of buildings and houses to display information in or on correspondingly used panes, in particular glass panes.

### BACKGROUND

The windows of a motor vehicle, especially a car, are usually made of laminated glass. Such laminated glass is not only used for windscreens, but in some cases also for side windows, rear windows, sunroofs and panoramic roofs. Laminated glass is produced by joining two or more panes of glass together using a thermoplastic bonding layer. In some cases, the thermoplastic layer is only applied to one pane.

LEDs that are oriented to shine towards the interior of a motor vehicle, especially a car, are used to provide interior lighting or to provide information to the driver or another occupant of the vehicle. Light sources, such as front lights, rear lights, the high-mounted brake light and additional brake lights or indicators, which are aligned so that they shine outwards, on the other hand, provide exterior lighting for the vehicle.

In the past, attempts have already been made to integrate LED lighting as an integral part of vehicle components, for example to provide interior lighting for the vehicle. One approach, for example, is to integrate LEDs into the glazing of a vehicle, in particular into the thermoplastic connecting layer between two panes of glass.

At present, however, no solutions are known in which LEDs can be integrated into vehicle components that appear transparent, such as the windows of a motor vehicle, so that only interior or exterior lighting is provided. For example, the light emitted by the LEDs when used in the rear window as a brake light should preferably only be emitted outwards, as light emitted into the vehicle interior can dazzle the driver. According to road traffic regulations, no red light, for example, may be emitted to the front, which is why the LEDs must be prevented from emitting into the vehicle interior. Similarly, when integrating a transparent display element into the windshield or the vehicle side window, for example, the aim is to prevent the information displayed on it from being readable from outside the vehicle.

In order to integrate LEDs into vehicle components that appear transparent, it is advisable to use sapphire chips on LED foils with the highest possible transparency (small pads and only the smallest possible metallic conductor track widths). However, due to the intrinsic radiation behavior of the chips, it is not possible to prevent light from being emitted against the main emission direction of the chips. At present, there are no known ways of suppressing this behavior while retaining the technology-specific advantages (e.g. high transparency). By laminating a fully tinted PVB film, radiation against the main emission direction can be modified and reduced, but such a tinted film has negative effects on the transparency of the application

There is a need to counteract the aforementioned problems and to provide an essentially transparent optoelectronic lighting device, for example a vehicle windshield, which comprises optoelectronic semiconductor components and is easy and inexpensive to manufacture.

### SUMMARY OF THE INVENTION

This and other needs are met by an optoelectronic lighting device with the features of claim 1 and a method for manufacturing an optoelectronic lighting device with the features of claim 17. Embodiments and further embodiments of the invention are described in the dependent claims.

An optoelectronic lighting device according to the invention comprises a first at least partially transparent embedding layer. Furthermore, the lighting device comprises at least one at least partially transparent carrier substrate arranged on the first embedding layer, on the side of which facing the first embedding layer a structured electrically conductive layer and at least one optoelectronic semiconductor component are arranged. The carrier substrate with the structured electrically conductive layer and the at least one optoelectronic semiconductor component is arranged opposite the first embedding layer in such a way that the first embedding layer embeds the structured electrically conductive layer and the at least one optoelectronic semiconductor component. The at least one optoelectronic semiconductor component is further configured to emit light during intended use at least along a main emission direction through a top surface of the optoelectronic semiconductor component and in a direction opposite to the main emission direction through a bottom surface of the optoelectronic semiconductor component. In addition, at least one substantially opaque, in particular reflective, region is provided below the at least one optoelectronic semiconductor component, as viewed in the direction opposite to the main emission direction, which has a size dependent on at least two of
a vertical distance between the bottom surface of the optoelectronic semiconductor component and the opaque region;
a surface area of the bottom surface of the optoelectronic semiconductor component; and
a maximum emission angle of the light emitted by the bottom surface of the optoelectronic semiconductor component.

According to at least one embodiment, the opaque region is larger than a light cone of a light emitted through the bottom surface of the optoelectronic semiconductor component incident on the opaque region and smaller than 2 times the incident light cone. In particular, the opaque region is larger than a projection of a light cone of a light emitted by the bottom surface of the optoelectronic semiconductor component and impinging on a surface of the opaque region. At the same time, the opaque region is smaller than 2 times the projection of the light cone incident on the surface of the opaque region.

An essential aspect of the invention is to integrate LEDs into a component/layer that appears transparent, such as the windows of a motor vehicle, so that these emit light in only one direction, for example into the interior or exterior of a vehicle. For this purpose, optoelectronic semiconductor components are arranged on an at least partially transparent carrier substrate and electrically contacted by means of a structured electrically conductive layer, and an opaque or reflective region is provided below the optoelectronic semiconductor components as seen in the direction opposite to the main emission direction, which prevents light emission from the component/layer in the direction opposite to the main emission direction. The opaque or reflective region is dimensioned and positioned below the optoelectronic semiconductor components in such a way that the component/layer still appears transparent, at least to the human eye of a user of the component (e.g. the driver or passenger of a vehicle). The size of the opaque or reflective region is determined as a function of at least one of a vertical distance between an bottom surface of the optoelectronic semiconductor component and the opaque region, a surface area of the bottom surface of the optoelectronic semiconductor component, and a maximum emission angle of the light emitted by the bottom surface of the optoelectronic semiconductor component.

According to at least one embodiment, the structured electrically conductive layer has at least a first region and a second region that is electrically insulated from the first region. The first region is coupled to a first electrical connection surface of the optoelectronic semiconductor component and the second region is coupled to a second electrical connection surface of the optoelectronic semiconductor component. The structured electrically conductive layer or the first and second regions of the structured electrically conductive layer can serve to supply the at least one optoelectronic semiconductor component with electrical energy and/or a data signal. The structured electrically conductive layer can consist of a conductive material, such as copper. The regions of the structured electrically conductive layer can be coated and/or blackened in order to reduce the reflectance of the outer surface area of the at least one electrical line. The coating can be a palladium or molybdenum coating, for example. It may be desirable for regions of the structured electrically conductive layer to be particularly reflective.

According to at least one embodiment, the structured electrically conductive layer comprises a substantially transparent material, such as indium tin oxide (ITO). Such a material can, for example, increase the transparency of the optoelectronic lighting device.

According to at least one embodiment, the opaque region is formed by a third region of the structured electrically conductive layer that is electrically insulated from the first and second regions. The third region may be a continuous region which is arranged below the at least one optoelectronic semiconductor component and which is electrically insulated from the first and second regions.

According to at least one embodiment, however, the opaque region is formed by a partial region of the second region of the structured electrically conductive layer. The sub-region may, for example, be a continuous region/area that is arranged below the at least one optoelectronic semiconductor component.

According to at least one embodiment, the first and second regions of the structured electrically conductive layer and, in the case of a third region, also the third region of the structured electrically conductive layer are separated from one another by an insulating layer. The insulating layer can, for example, be arranged on the second or the third region and between the first, second and third regions.

According to at least one embodiment, the optoelectronic lighting device also comprises a first conductor path section which connects the first region of the structured electrically conductive layer to the first electrical connection surface of the optoelectronic semiconductor component. The first conductor path section is arranged on the insulating layer and extends thereon from the first region of the structured electrically conductive layer to the first electrical connection surface of the optoelectronic semiconductor component.

According to at least one embodiment, the optoelectronic lighting device also comprises a second conductor path section which connects the second region of the structured electrically conductive layer to the second electrical connection surface of the optoelectronic semiconductor component. The second conductor path section is arranged on the insulating layer and extends on the latter from the second region of the structured electrically conductive layer to the second electrical connection surface of the optoelectronic semiconductor component.

According to at least one embodiment, the optoelectronic lighting device further comprises a second at least partially transparent embedding layer, which is arranged on a side of the carrier substrate opposite the optoelectronic semiconductor component.

In some embodiments, the first and/or second at least partially transparent embedding layer is formed by a melting material layer, an adhesive layer, a hot melt adhesive layer, a resin, such as ethylene vinyl acetate (EVA), polyvinyl butyral (PVB), or by an ionomer-based system. In particular, the first and/or second at least partially transparent embedding layer may comprise or consist of an at least partially transparent plastic, in particular an at least partially transparent film, in particular a flexible film. At least the first at least partially transparent embedding layer may, for example, be formed by a protective varnish embedding the structured electrically conductive layer and the at least one optoelectronic semiconductor component. In some embodiments, the first and/or second at least partially transparent embedding layer may be blackened.

In some embodiments, the carrier substrate with the structured electrically conductive layer arranged thereon and the at least one optoelectronic semiconductor component is embedded between the first and the second at least partially transparent embedding layer. The first and second at least partially transparent embedding layers can, for example, compensate for a height or topography of the structured electrically conductive layer and the at least one optoelectronic semiconductor component. According to at least one embodiment, the opaque region is arranged on a side of the carrier substrate opposite the optoelectronic semiconductor component and is embedded in the second at least partially transparent embedding layer.

According to at least one embodiment, the opaque region is formed by a material accumulation of an opaque material, for example a reflective and/or light-absorbing material, which is arranged on a side of the carrier substrate opposite the optoelectronic semiconductor component. For example, the opaque region can also be formed by an accumulation of a reflective material and a light-absorbing material encasing the reflective material. A portion of the material accumulation facing the at least one optoelectronic semiconductor component can be configured to be reflective, and lateral portions and a portion of the material accumulation facing away from the at least one optoelectronic semiconductor component can, for example, be configured to be light-absorbing.

In some embodiments, the at least partially transparent carrier substrate comprises at least one of the materials PET, polycarbonate, PMMA, and PEN. In particular, the flexible carrier substrate may comprise a substantially transparent material that additionally has flexible or elastic properties. The term “flexible” can be understood to mean that the carrier substrate is pliable or elastic and can be formed into a desired shape without destruction and without the effect of large forces.

In some embodiments, the optoelectronic light emitting device comprises a transparent pane disposed on the first embedding layer. For example, the transparent pane may be formed by a glass pane, but the transparent pane may also be formed by a transparent plastic such as Plexiglas or a transparent film. In some embodiments, the transparent pane is formed by a transparent, flexible film.

In some embodiments, the optoelectronic lighting device comprises a further transparent pane, in particular a glass pane, wherein the first and the optional second embedding layer are arranged between the two transparent panes, in particular glass panes. The first and the optional second embedding layer can, for example, be formed by a thermoplastic compound layer laminated between two glass panes. Accordingly, the optoelectronic lighting device can form a laminated glass pane in which a plurality of lighting elements are integrated.

According to at least one embodiment, the optoelectronic lighting device also comprises an anti-reflective layer arranged on the transparent pane. An anti-reflective coating on the surface of the transparent pane can reduce back reflections inside the optoelectronic lighting device.

In some embodiments, the at least one optoelectronic semiconductor component is formed by a luminous element or an LED. In some embodiments, the at least one optoelectronic semiconductor component forms a luminous dot, wherein the totality of several such luminous dots can form a luminous symbol or luminous lettering during intended use of the optoelectronic lighting device. However, the illuminated dots can also be arranged randomly in relation to one another and form a dot-shaped pattern, for example. The term illuminated dot is not to be understood as a dot-shaped element, but as an area of an illuminated surface defined by the size of the semiconductor component.

In some embodiments, the at least one optoelectronic semiconductor component may be formed by a light emitting element or LED comprising a conversion material. For example, the conversion material may be disposed over a light emitting region of the semiconductor device and may be configured to convert the light emitted by the semiconductor device into light of a different wavelength.

In some embodiments, the at least one optoelectronic semiconductor component is formed by an LED, in particular an LED chip. An LED may in particular be referred to as a mini-LED, which is a small LED, for example with edge lengths of less than 200 μm, in particular up to less than 40 μm, in particular in the range from 200 μm to 10 μm. Another range is between 150 μm and 40 μm. At these spatial dimensions, the optoelectronic semiconductor component is almost invisible to the human eye.

The LED may also be referred to as a micro LED, also known as a μLED, or a μLED chip, particularly in the case where the edge lengths are in the range of 100 μm to 3 μm. In some embodiments, the LED may have a spatial dimension of 90×150 μm or a spatial dimension of 75×125 μm.

In some embodiments, the mini-LED or μLED chip may be an unhoused semiconductor chip. Unhoused may mean that the chip does not have a package around its semiconductor layers, such as a “chip die”. In some embodiments, unhoused may mean that the chip is free of any organic material. Thus, the unhoused device does not contain any organic compounds that contain carbon in covalent bonding.

In some embodiments, the at least one optoelectronic semiconductor component may comprise a mini-LED or μLED chip configured to emit light of a selected color. In some embodiments, two or more optoelectronic semiconductor components may form a pixel, such as an RGB pixel comprising three mini-LEDs or μLED chips. An RGB pixel can, for example, emit light of the colors red, green and blue as well as any mixed colors. In some embodiments, more than three optoelectronic semiconductor components can also form a pixel, such as an RGBW pixel comprising four mini-LEDs or μLED chips. An RGBW pixel can, for example, emit light of the colors red, green, blue and white as well as any mixed colors. For example, white light or red light or green light or blue light can be generated in the form of a full conversion using an RGBW pixel.

In some embodiments, the at least one optoelectronic semiconductor component is assigned to an integrated circuit for controlling the latter. In some embodiments, 2 or more optoelectronic semiconductor components are each assigned to an integrated circuit for their control. For example, one RGB pixel can be assigned to an integrated circuit (IC). The integrated circuit or integrated circuits may, for example, be formed by a particularly small integrated circuit, such as a micro-integrated circuit (μIC).

In some embodiments, a layer with light-scattering particles can be arranged above the at least one optoelectronic semiconductor component or above each pixel. The use of such a layer with the light-scattering particles can in particular improve a homogeneous emission of the light of the at least one optoelectronic semiconductor component.

The plurality of optoelectronic semiconductor components can form a luminous symbol or luminous lettering during an intended use of the optoelectronic lighting device. In the case of a plurality of optoelectronic semiconductor components, the lighting elements can form a symbol or an illuminated lettering as a whole during an intended use of the optoelectronic lighting device, or the lighting elements can form several symbols or illuminated lettering during an intended use of the optoelectronic lighting device.

The invention also relates to a method of manufacturing an optoelectronic lighting device comprising the steps of:
Providing a first at least partially transparent embedding layer;
Providing an at least partially transparent carrier substrate with
   a structured electrically conductive layer and at least one optoelectronic semiconductor component, the at least one optoelectronic semiconductor component being configured to emit light during an intended use at least along a main emission direction through a top surface of the optoelectronic semiconductor component and in a direction opposite to the main emission direction through a bottom surface of the optoelectronic semiconductor component, and
   a substantially opaque, in particular reflective, region, which is provided below the at least one optoelectronic semiconductor component when viewed in the direction opposite to the main emission direction, the opaque region having a size as a function of a vertical distance between the bottom surface of the optoelectronic semiconductor component and the opaque region and/or as a function of the size of the bottom surface of the optoelectronic semiconductor component and/or as a function of a maximum emission angle of the light emitted by the bottom surface of the optoelectronic semiconductor component; and
Arranging the carrier substrate on the first embedding layer in such a way that the structured electrically conductive layer and the at least one optoelectronic semiconductor component are embedded in the first embedding layer.

In some embodiments, the step of providing the carrier substrate comprises applying the structured electrically conductive layer to the carrier substrate such that the structured electrically conductive layer has at least a first region and a second region electrically insulated from the first region. In addition, the step of applying the structured electrically conductive layer may comprise producing a third region of the structured electrically conductive layer that is electrically insulated from the first and second regions, wherein the third region forms the opaque region. Alternatively, however, a partial region of the second region of the structured electrically conductive layer can also form the opaque region.

In some embodiments, the step of providing the carrier substrate comprises applying an insulating layer to the third region or to the portion of the second region of the structured electrically conductive layer. A first conductor track section can also be formed on the insulating layer, which is electrically connected to the first region of the structured electrically conductive layer. In addition to this, a second conductor track section can also be formed on the insulating layer, which is electrically connected to the second region of the structured electrically conductive layer.

According to at least one embodiment, the step of providing the carrier substrate comprises arranging the at least one optoelectronic semiconductor component on the carrier substrate such that the first region of the structured electrically conductive layer is coupled to a first electrical connection surface of the at least one optoelectronic semiconductor component and the second region of the structured electrically conductive layer is coupled to a second electrical connection surface of the optoelectronic semiconductor component.

In some embodiments, the step of providing the carrier substrate comprises forming or providing the opaque region on an upper surface of the carrier substrate opposite the optoelectronic semiconductor component or on another surface located below the semiconductor device. The opaque region is formed in particular in the form of an accumulation of a light-absorbing and/or reflective material.

According to at least one embodiment, the method further comprises applying a second at least partially transparent embedding layer to a side of the carrier substrate opposite the first embedding layer such that the second and first embedding layers cover the carrier substrate and the components and layers disposed thereon.

According to at least one embodiment, the method further comprises applying a transparent pane, in particular a glass pane, to the first embedding layer.

In some embodiments, the method comprises a further step:
Arranging a further transparent pane, in particular glass pane, on the second embedding layer in such a way that the first and second embedding layers are arranged between the two transparent panes, in particular glass panes.

In some embodiments, the transparent pane, the first embedding layer, the second embedding layer and the optional further transparent pane are bonded together in a further lamination step, in particular under the action of pressure and/or temperature.

The optoelectronic lighting device according to the invention can have the following advantages:
Light emission in one direction only, so that no light is emitted into the interior of a vehicle, for example;
Increased system efficiency, as light initially emitted in the rear direction is redirected towards the main emission side and can be used;
Retention of the highest possible transparency, as shading/reflection only occurs locally. (Compared to the state of the art, where a tinted PVB film is laminated over the entire surface, this is a significant gain in transparency);
The integration of such locally structured or locally applied opaque regions is relatively inexpensive;
The use of anti-reflective glass can prevent annoying reflections or multiple reflections and thus increase the brilliance of the display elements.

### BRIEF DESCRIPTION OF THE DRAWINGS

In the following, embodiments of the invention are explained in more detail with reference to the accompanying drawings. They show, in each case schematically,

FIG. 1A to 1C a carrier substrate with an optoelectronic semiconductor component and the structure of a laminated glass pane;

FIGS. 2A and 2B the structure of an optoelectronic lighting device according to some aspects of the proposed principle;

FIGS. 3A and 3B the structure of another embodiment of an optoelectronic lighting device according to some aspects of the proposed principle;

FIGS. 4A to 5B the structure of further embodiments of an optoelectronic lighting device according to some aspects of the proposed principle;

FIG. 6 a sectional view of an optoelectronic lighting device according to some aspects of the proposed principle to illustrate the geometrical relationships; and

FIGS. 7 to 9B the structure of further embodiments of an optoelectronic lighting device according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

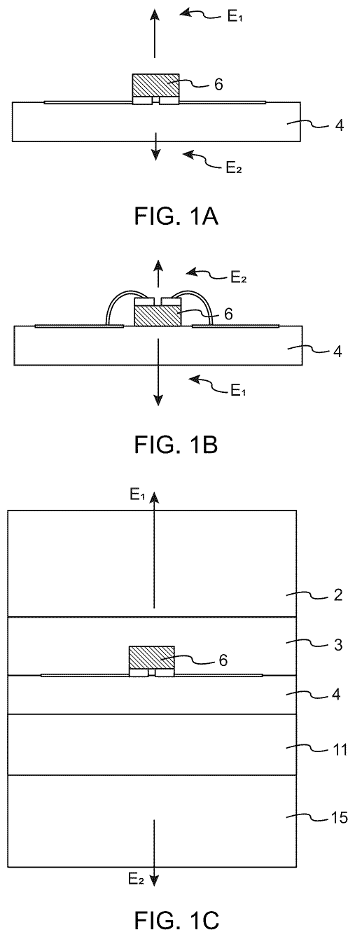

FIGS. 1A and 1B show two possible arrangements of an optoelectronic semiconductor element 6 on a carrier substrate 4. The main emission direction E₁ of the semiconductor element 6 can, as shown in FIG. 1A, either run away from the substrate 4 (chip last) or, as shown in FIG. 1B, through the substrate 4 (chip first). Electrical connection surfaces can be connected directly to a contact structure on the substrate 4 according to the design, or must be connected to a contact structure on the substrate 4 using wire bonds, for example. With chip first, the chip is contacted from above by means of wirebonds; with chip last, the chip is contacted from below by placing the chip on a contact structure.

FIG. 1C shows the structure of a laminated glass pane with a carrier substrate 4 as shown in FIG. 1A. The laminated glass pane comprises a first glass pane 2 and a second glass pane 15, as well as a first embedding layer 4 and a second embedding layer 11, which mechanically connect the two glass panes to each other. The carrier substrate 4 with the optoelectronic semiconductor component 6 is arranged between the two embedding layers 3, 11 and embedded in them. The laminated glass pane can be produced, for example, by laminating the two glass panes together by means of the two embedding layers 3, 11.

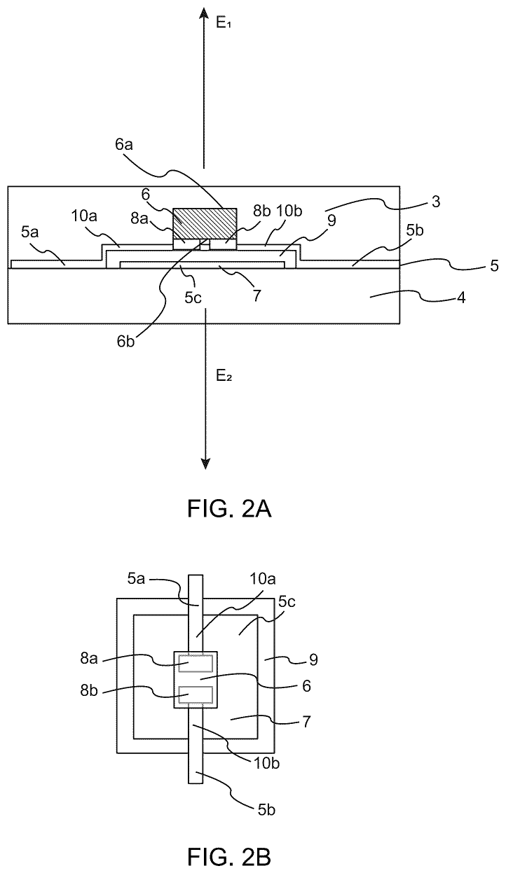

FIGS. 2A and 2B show the structure of an optoelectronic light-emitting device 1 according to some aspects of the proposed principle in a side view and in a top view. The light-emitting device 1 comprises an at least partially transparent embedding layer 3 on which an at least partially transparent carrier substrate 4 is arranged. A structured electrically conductive layer 5 and an optoelectronic semiconductor component 6 are arranged on the side of the carrier substrate 4 facing the first embedding layer 3. The first embedding layer 3 embeds the structured electrically conductive layer 5 and the optoelectronic semiconductor component 6.

During intended use, the optoelectronic semiconductor component 6 is configured to emit light along a main emission direction E₁ through a top surface 6a of the optoelectronic semiconductor component 6 and in a direction E₂ opposite to the main emission direction through a bottom surface 6b of the optoelectronic semiconductor component 6.

The structured electrically conductive layer 5 is designed in such a way that it has a first 5a, a second 5b and a third 5c region, which are each electrically insulated from one another. An insulating layer 9 is arranged on the third region 5c or between the first and third and the second and third regions.

A first conductive path section 10a is arranged on the insulating layer 9, which connects the first region 5a of the structured electrically conductive layer 5 to a first electrical connection surface 8a of the optoelectronic semiconductor component 6, and a second conductive path section 10b is arranged on the insulating layer 9, which connects the second region 5b of the structured electrically conductive layer 5 to a second electrical connection surface 8b of the optoelectronic semiconductor component 6.

A substantially opaque, in particular reflective, region 7 is provided below the optoelectronic semiconductor component 6 when viewed in the direction E₂ opposite the main emission direction. In the present case, this is formed by the third region of the structured electrically conductive layer 5. This is intended to absorb light emitted by the semiconductor component 6 in the direction E₂ opposite to the main emission direction or to reflect it in the direction of the main emission direction E₁. The opaque region has a size depending on a vertical distance d between the bottom surface 6b of the optoelectronic semiconductor component 6 and the opaque region 7, the surface area of the bottom surface 6b of the optoelectronic semiconductor component 6, and the maximum emission angle α of the light emitted by the bottom surface 6 of the optoelectronic semiconductor component 6.

Due to such an adapted contacting layout for the optoelectronic semiconductor component with a partially larger contact surface or a non-current-carrying area, a large part of the light emitted in the direction E₂ against the main emission direction can be absorbed or reflected forwards. The novel contacting layout is based on a double-layer metallization with a continuous and, in particular, electrically insulated and therefore non-current-carrying metallization below the optoelectronic semiconductor component 6 (opaque local mirror coating). The different metallization layers can be electrically isolated from each other by means of the insulation layer 9.

The first and second regions 5a, 5b of the structured electrically conductive layer 5 and the conductor track sections 10a, 10b can be made thin so that they do not impair the transparency of the optoelectronic lighting device 1. The opaque region 7, here in the form of the third region 5c of the structured electrically conductive layer 5, may have a certain size, but may still be invisible to an observer of the optoelectronic lighting device 1 due to the local insertion and a selected dimensioning. The opaque region 7 can, for example, have a diameter or edge lengths in the range of <500 μm, <200 μm or <50 μm, depending on the size of the semiconductor component 6.

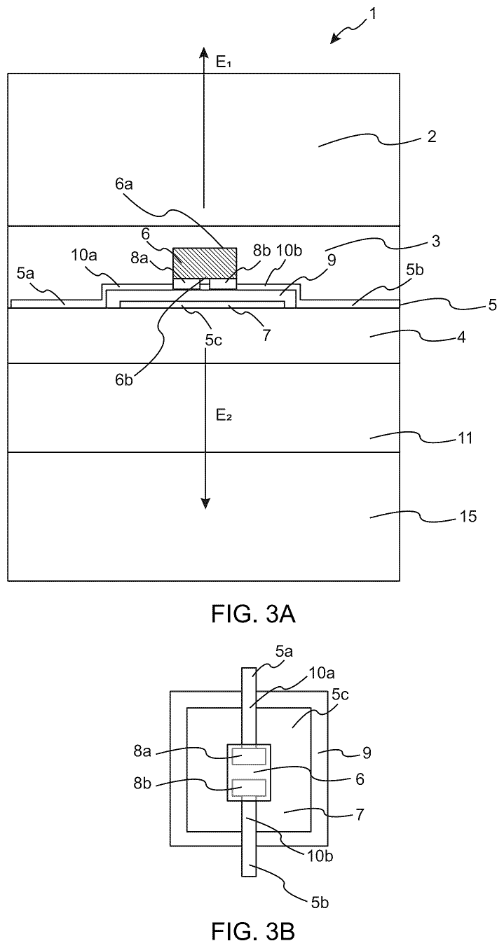

FIGS. 3A and 3B show the structure of an optoelectronic light-emitting device 1 according to some aspects of the proposed principle in a side view and in a plan view. The light-emitting device 1 comprises a transparent pane 2, in particular a glass pane, on which a first at least partially transparent embedding layer 3 is arranged. Furthermore, the light-emitting device 1 comprises a carrier substrate 4 on whose side facing the first embedding layer 3 a structured electrically conductive layer 5 and an optoelectronic semiconductor component 6 are arranged. The first embedding layer 3 embeds the structured electrically conductive layer 5 and the optoelectronic semiconductor component 6.

During intended use, the optoelectronic semiconductor component 6 is configured to emit light along a main emission direction E₁ through a top surface 6a of the optoelectronic semiconductor component 6 and in a direction E₂ opposite to the main emission direction through a bottom surface 6b of the optoelectronic semiconductor component 6.

On the side of the carrier substrate 4 opposite the first embedding layer 3, a second at least partially transparent embedding layer 11 is arranged, which covers the carrier substrate 4, and a further transparent pane 15, in particular a glass pane, is arranged above the second embedding layer 11.

The composite of the layers or panes shown is mechanically connected to each other, for example by laminating the two transparent panes 2, 15 together through the two embedding layers 3, 11. Alternatively, the composite of the layers or panes shown can be glued together.

The structured electrically conductive layer 5 is designed in such a way that it has a first 5a, a second 5b and a third 5c region, which are each electrically insulated from one another. An insulating layer 9 is arranged on the third region 5c or between the first and third and the second and third regions. A first conductive path section 10a is arranged on the insulating layer 9, which connects the first region 5a of the structured electrically conductive layer 5 to a first electrical connection surface 8a of the optoelectronic semiconductor component 6, and a second conductive path section 10b is arranged on the insulating layer 9, which connects the second region 5b of the structured electrically conductive layer 5 to a second electrical connection surface 8b of the optoelectronic semiconductor component 6.

A substantially opaque, in particular reflective, region 7 is provided below the optoelectronic semiconductor component 6 when viewed in the direction E₂ opposite the main emission direction. In the present case, this is formed by the third region of the structured electrically conductive layer 5. This is intended to absorb light emitted by the semiconductor component 6 in the direction E₂ opposite to the main emission direction or to reflect it in the direction of the main emission direction E₁. The opaque region has a size depending on a vertical distance d between the bottom surface 6b of the optoelectronic semiconductor component 6 and the opaque region 7, the surface area of the bottom surface 6b of the optoelectronic semiconductor component 6, and the maximum emission angle α of the light emitted by the bottom surface 6 of the optoelectronic semiconductor component 6.

Due to such an adapted contacting layout for the optoelectronic semiconductor component with a partially larger contact surface or a non-current-carrying area, a large part of the light emitted in the direction E₂ against the main emission direction can be absorbed or reflected forwards. The novel contacting layout is based on a double-layer metallization with a continuous and, in particular, electrically insulated and therefore non-current-carrying metallization below the optoelectronic semiconductor component 6 (opaque local mirror coating). The different metallization layers can be electrically isolated from each other by means of the insulation layer 9.

The first and second regions 5a, 5b of the structured electrically conductive layer 5 and the conductor track sections 10a, 10b can be made thin so that they do not impair the transparency of the optoelectronic lighting device 1. The opaque region 7, here in the form of the third region 5c of the structured electrically conductive layer 5, may have a certain size, but may still be invisible to an observer of the optoelectronic lighting device 1 due to the local insertion and a selected dimensioning. The opaque region 7 can, for example, have a diameter or edge lengths in the range of <500 μm, <200 μm or <50 μm, depending on the size of the semiconductor component 6.

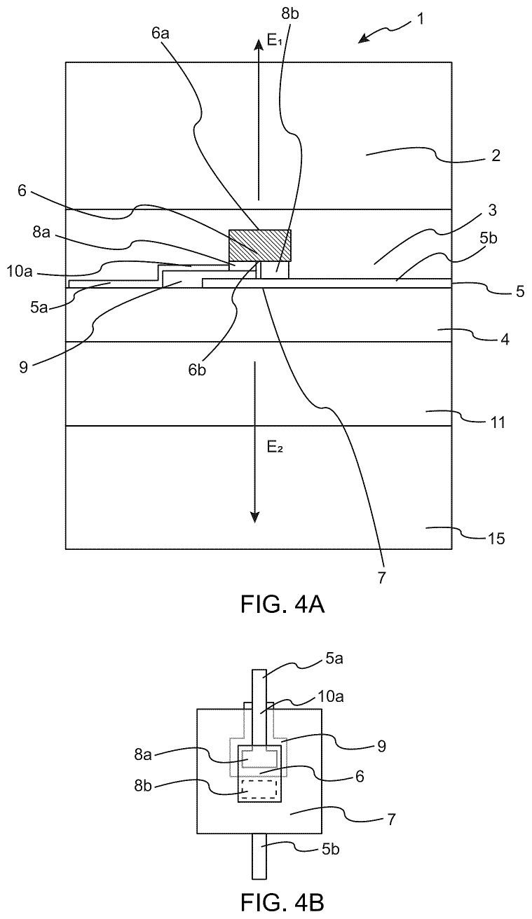

FIGS. 4A and 4B show the structure of a further embodiment of an optoelectronic lighting device 1 according to some aspects of the proposed principle in a side view and in a top view. In contrast to the embodiment shown in FIGS. 3A and 3B, the structured electrically conductive layer 5 does not have a third region selected as the opaque region 7, but the second region 5b of the structured electrically conductive layer 5 extends below the entire semiconductor device 6 and a portion of the second region acts as the opaque region 7. The first and second regions 5a, 5b are electrically isolated from each other by the insulating layer 9, which is applied in some areas to the subregion of the second region 5b. The optoelectronic lighting device 1 also has only a first conductor track section 10a, which is arranged on the insulating layer 9 and which connects the first region 5a of the structured electrically conductive layer 5 to a first electrical connection surface 8a of the optoelectronic semiconductor component 6. The second electrical connection surface 8b, on the other hand, is electrically connected to the second region 5b via an enlarged solder pad or an elevation on the second region 5b.

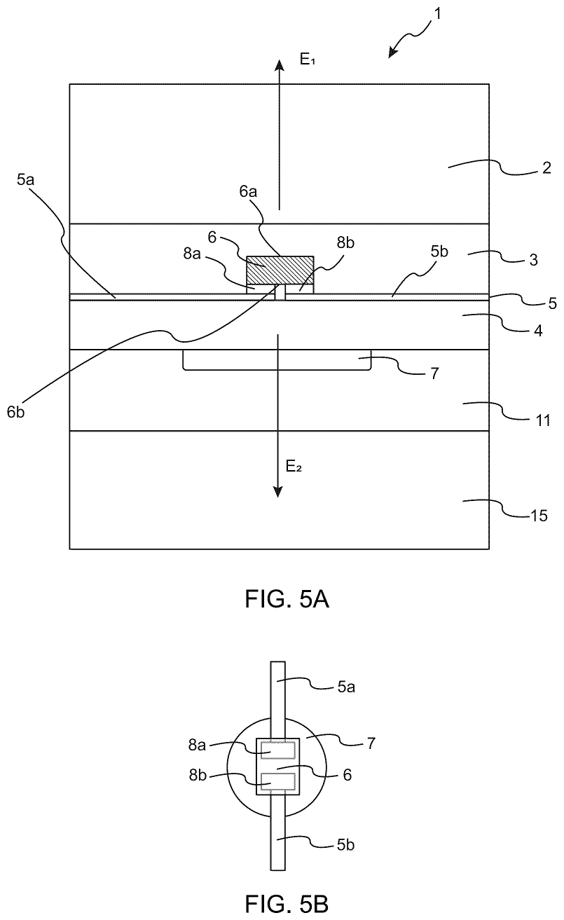

FIGS. 5A and 5B show the structure of a further embodiment of an optoelectronic lighting device 1 according to some aspects of the proposed principle in a side view and in a top view. In contrast to the embodiment shown in FIGS. 3A and 3B, as well as 4A and 4B, the opaque region 7 is not formed by the structured electrically conductive layer 5, but by an accumulation of material arranged on the rear side of the carrier substrate 4. The accumulation of material is embedded in the second embedding layer 11.

The accumulation of material can, for example, be a locally printed structured metal layer, or locally printed colored dots, reflectors, lenses or other materials that absorb, reflect or deflect light emitted in the direction E₂ opposite to the main emission direction.

The accumulation of material should be dimensioned in such a way that it is large enough that light emitted in the direction E₂ against the main emission direction cannot shine past the opaque region 7 at the side and at the same time it should be small enough that the transparency of the optoelectronic lighting device 1 is not significantly impaired. In addition, the opaque region 7 should be arranged sufficiently precisely below the semiconductor component 6 so that light emitted in the direction E₂ against the main emission direction cannot shine past the opaque region 7 at the side.

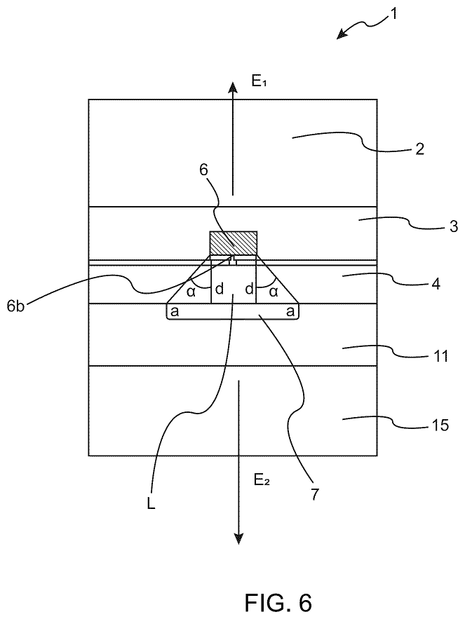

FIG. 6 shows a sectional view of an optoelectronic lighting device 1 according to some aspects of the proposed principle to illustrate the geometric relationships with regard to the size of the opaque region 7. The figure shows the maximum emission angle α of a light emitted through the bottom surface of the semiconductor component 6, so that a correspondingly emitted light cone L results. The size of the opaque region 7 results accordingly from the size of the bottom surface 6b of the semiconductor component 6 plus an additional area due to the divergence of the light cone L, which increases with the distance d between the bottom surface 6b of the optoelectronic semiconductor component 6 and the opaque region 7. The additional area can, for example, be ring-shaped or approximately ring-shaped with a width a. The width a can be determined using the trigonometric relationship a=tan(α)*d can be determined. As the distance d increases and the maximum emission angle α increases (at least between 0° and) 90°, the opaque region 7 also increases accordingly.

It goes without saying that, accordingly, the distance d between the bottom surface 6b of the optoelectronic semiconductor component 6 and the opaque region 7 is kept as small as possible. For example, by forming the opaque region 7 on the same side of the carrier substrate 4 as the semiconductor component 6, or, for example, by making the carrier substrate and any other layers arranged between the bottom surface 6b of the optoelectronic semiconductor component 6 and the opaque region 7 as thin as possible.

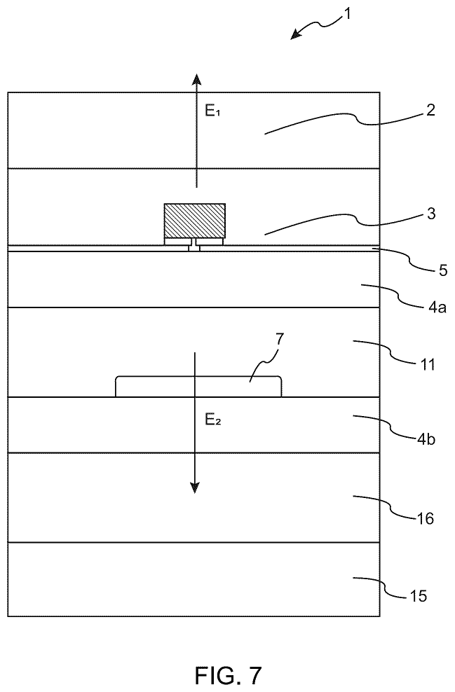

FIG. 7 shows a further embodiment of an optoelectronic lighting device 1, in which the opaque region 7 is arranged on a further carrier substrate 4b. The two carrier substrates 4a, 4b together with the first, the second and a third embedding layer 3, 11, 16 form a composite which is laminated between the two transparent panes 2, 15. Such an arrangement has the advantage that the two substrates 4a, 4b with the respective components arranged thereon can be produced separately and subsequently bonded together. For example, it is also possible to arrange the opaque region 7 directly on one of the embedding layers and thus save the second carrier substrate 4b.

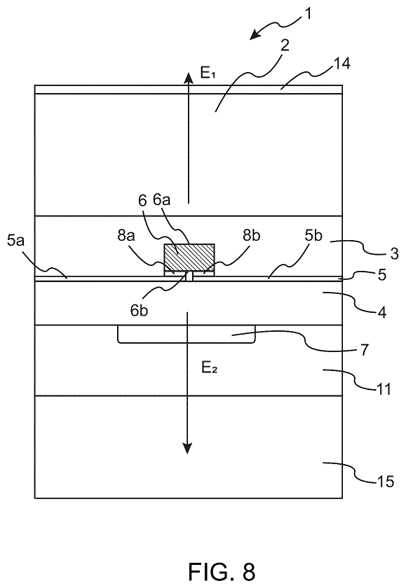

In addition, as shown as an example in the embodiment in FIG. 8, an anti-reflective layer 14 can be arranged on the transparent panes 2. This can reduce back reflections (Fresnel reflections at the interface between glass and air) of the light emitted in the main emission direction, which can arise through the surface of the transparent panes 2. Alternatively, such anti-reflective layers 14 can also be laminated between the other layers of the lighting device 1.

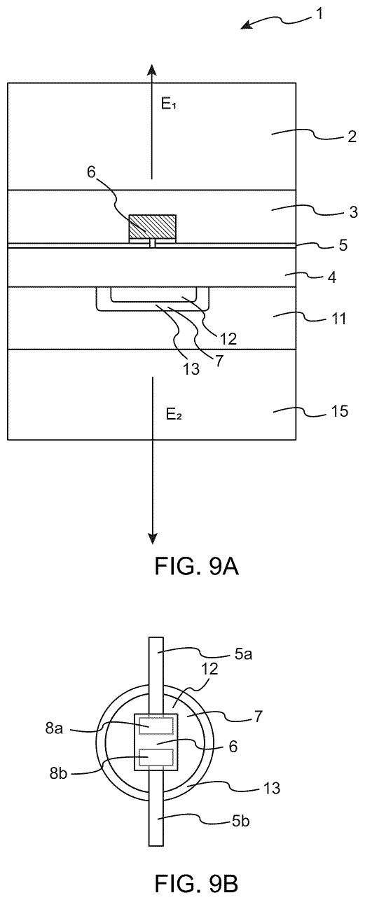

FIGS. 9a and 9b show the structure of a further embodiment of an optoelectronic lighting device 1 according to some aspects of the proposed principle in a side view and in a top view. The opaque region 7 is formed by an accumulation of a reflective material 12 and a light-absorbing material 13 encasing the reflective material. The light-absorbing material can additionally attenuate or prevent possible transmission through the opaque region 7. The opaque region 7 can be designed accordingly, for example, with black dots printed in white. Reflection in the direction of the main emission direction E₁ is achieved by means of a white material 12 and any light that passes through the white material is absorbed by a black coating 13 of the white dot.

### REFERENCE LIST

1 optoelectronic lighting device
2 first glass pane
3 first at least partially transparent embedding layer
4 carrier substrate
5 structured electrically conductive layer
5a first region
5b second region
5c third region
6 optoelectronic semiconductor component
6a top surface
6b bottom surface
7 opaque region
8a, 8b connection surface
9 insulation layer
10a, 10b conductive path portion
11 second at least partially transparent embedding layer
12 reflective material
13 light-absorbing material
14 anti-reflective layer
15 second glass pane
16 third at least partially transparent embedding layer
E₁ main emission direction
E₂ direction opposite to the main emission direction
L light cone
d distance
a width
α emission angle

1. An optoelectronic lighting device comprising:
a first at least partially transparent embedding layer; and
at least one at least partially transparent carrier substrate arranged on the first embedding layer, on whose side facing the first embedding layer a structured electrically conductive layer and at least one optoelectronic semiconductor component are arranged;
wherein the first embedding layer embeds the structured electrically conductive layer and the at least one optoelectronic semiconductor component;
wherein the at least one optoelectronic semiconductor component during an intended use is configured to emit light at least along a main emission direction through a top surface of the optoelectronic semiconductor component and in a direction opposite to the main emission direction through a bottom surface of the optoelectronic semiconductor component;
wherein a substantially opaque, in particular reflective, region is provided below the at least one optoelectronic semiconductor component as viewed in the direction opposite to the main emission direction, which region comprises a size dependent on at least two values of
a vertical distance between the bottom surface of the optoelectronic semiconductor component and the opaque region;
a surface area of the bottom surface of the optoelectronic semiconductor component; and
a maximum emission angle of the light emitted by the bottom surface of the optoelectronic semiconductor component; and
wherein the opaque region is larger than a light cone incident on the opaque region of a light emitted by the bottom surface of the optoelectronic semiconductor component and smaller than 2 times the incident light cone.

2. (canceled)

3. The optoelectronic lighting device according to claim 1, wherein the structured electrically conductive layer comprises at least a first and a second region electrically insulated from the first region, wherein the first region is coupled to a first electrical connection surface of the optoelectronic semiconductor component and the second region is coupled to a second electrical connection surface of the optoelectronic semiconductor component.

4. The optoelectronic lighting device according to claim 3, wherein the opaque region is formed by a third region of the structured electrically conductive layer which is electrically insulated from the first and second regions.

5. The optoelectronic lighting device according to claim 3, wherein the opaque region is formed by a partial region of the second region of the structured electrically conductive layer layer.

6. The optoelectronic lighting device according to claim 3, wherein the first and the second region of the structured electrically conductive layer, as well as the optional third region of the structured electrically conductive layer are separated from each other by an insulating layer.

7. The optoelectronic lighting device according to claim 6, further comprising a first conductive path portion which connects the first region of the structured electrically conductive layer to the first electrical connection surface of the optoelectronic semiconductor component, and which is arranged on the insulating layer.

8. The optoelectronic lighting device according to claim 6, further comprising a second conductive path portion which connects the second region of the structured electrically conductive layer to the second electrical connection surface of the optoelectronic semiconductor component, and which is arranged on the insulating layer.

9. The optoelectronic lighting device according to claim 1, further comprising a second at least partially transparent embedding layer arranged on a side of the carrier substrate opposite to the optoelectronic semiconductor component.

10. The optoelectronic lighting device according to claim 9, wherein the opaque region is embedded in the second at least partially transparent embedding layer.

11. The optoelectronic lighting device according to claim 1, wherein the opaque region is formed by a material accumulation of an opaque material which is arranged on a side of the carrier substrate opposite the optoelectronic semiconductor component.

12. The optoelectronic lighting device according to claim 11, wherein the opaque region is formed by a material accumulation of a reflective material and a light-absorbing material encasing the reflective material.

13. The optoelectronic lighting device according to claim 1,
wherein the carrier substrate comprises at least one of PET, PC, and PEN.

14. The optoelectronic lighting device according to claim 1, further comprising a transparent pane, in particular glass pane, which is arranged on the first embedding layer.

15. The optoelectronic lighting device according to claim 14, further comprising a further transparent pane, in particular glass pane, wherein the first and the optional second embedding layer as well as the carrier substrate are arranged between the two transparent panes, in particular glass panes.

16. The optoelectronic lighting device according to claim 1, further comprising an anti-reflective layer arranged on the first embedding layer or the transparent pane.

17. A method for manufacturing an optoelectronic lighting device comprising the steps of:
Providing a first at least partially transparent embedding layer;
Providing an at least partially transparent carrier substrate with
a structured electrically conductive layer and at least one optoelectronic semiconductor component, the at least one optoelectronic semiconductor component being configured to emit light during intended use at least along a main emission direction through a top surface of the optoelectronic semiconductor component and in a direction opposite to the main emission direction through a bottom surface of the optoelectronic semiconductor component, and
a substantially opaque, in particular reflective, region which is provided below the at least one optoelectronic semiconductor component as viewed in the direction opposite to the main emission direction, the opaque region having a size as a function of a vertical distance between the bottom surface of the optoelectronic semiconductor component and the opaque region and/or as a function of the size of the bottom surface of the optoelectronic semiconductor component and/or as a function of a maximum emission angle of the light emitted by the bottom surface of the optoelectronic semiconductor component, and wherein the opaque region is larger than a light cone incident on the opaque region of a light emitted by the bottom surface of the optoelectronic semiconductor component and smaller than 2 times the incident light cone; and
arranging the carrier substrate on the first embedding layer in such a way that the structured electrically conductive layer and the at least one optoelectronic semiconductor component are embedded in the first embedding layer.

18. The method according to claim 17, wherein the step of providing the carrier substrate comprises applying the structured electrically conductive layer to the carrier substrate such that the structured electrically conductive layer comprises at least a first and a second region electrically insulated from the first region.

19. The method according to claim 18, wherein the step of applying the structured electrically conductive layer comprises creating a third region of the structured electrically conductive layer electrically insulated from the first and second region, wherein the third region forms the opaque region.

20. The method according to claim 18, wherein a partial region of the second region of the structured electrically conductive layer forms the opaque region.

21. The method according to claim 19, wherein the step of providing the carrier substrate comprises applying an insulating layer to the third region or to the partial region of the second region of the structured electrically conductive layer.

22. The method according to claim 21, wherein the step of providing the carrier substrate comprises forming a first conductive path portion on the insulating layer, which is electrically connected to the first region of the structured electrically conductive layer.

23. The method according to claim 22, wherein the step of providing the carrier substrate comprises forming a second conductive path portion on the insulating layer, which is electrically connected to the second region of the structured electrically conductive layer.

24. The method according to claim 17, wherein the step of providing the carrier substrate comprises arranging the at least one optoelectronic semiconductor component on the carrier substrate such that, that the first region of the structured electrically conductive layer is coupled to a first electrical connection surface of the optoelectronic semiconductor component and the second region of the structured electrically conductive layer is coupled to a second electrical connection surface of the optoelectronic semiconductor component.

25. The method according to claim 17, wherein the step of providing the carrier substrate comprises forming the opaque region on a top surface of the carrier substrate opposite to the optoelectronic semiconductor component.

26. The method according to claim 17, further comprising applying a second at least partially transparent embedding layer to a side of the carrier substrate opposite to the first embedding layer.

27. The method according to claim 17, further comprising arranging a transparent pane, in particular a glass pane, on the first embedding layer.

28. The method according to claim 27,
further comprising arranging a further transparent pane, in particular glass pane, on the second embedding layer in such a way that the first and the second embedding layer are arranged between the two transparent panes, in particular glass panes.

29. The method according to claim 27, further comprising a lamination step in which the transparent pane, the first embedding layer, the optional second embedding layer and the optional further transparent pane are bonded together.
